(19) United States
(12) Patent Application Publication
(10) Pub. No.: US 2007/0267945 A1
(43) Pub. Date: Nov. 22, 2007

(54) Ultrasound Transducer and Method for Implementing High Aspect Ration Bumps for Flip-Chip Two Dimensional Arrays

(75) Inventor: Wojtek Sudol, Andover, MA (US)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/573,753

(22) PCT Filed: Aug. 15, 2005
(86) PCT No.: PCT/IB05/52686

§ 371 Date: Feb. 15, 2007

Related U.S. Application Data
(60) Provisional application No. 60/602,583, filed on Aug. 18, 2004.

(51) Int. Cl. H01L 41/22; B06B 1/06

(52) U.S. Cl. 310/334; 29/25.35

(57) ABSTRACT

An ultrasound transducer (100) comprises an integrated circuit (52) and an array of acoustic elements (92,94,96) coupled to the integrated circuit via flip chip bumps (76,78). The flip chip bumps comprise high aspect ratio bumps having an aspect ratio greater than 1:1. The aspect ratio comprises a ratio of a bump height (82) to a bump width (84).

This application relates to the application entitled “Transducer Arrays for Medical Ultrasound and Method of Making the Same”, Bernard Savord et al., Attorney Docket US040334, filed concurrently herewith and incorporated herein by reference in its entirety.

The present disclosure generally relates to transducer arrays for use in medical ultrasound, and more particularly, to a method and apparatus for implementing high aspect ratio bumps for flip-chip two-dimensional arrays.

In medical ultrasound, two-dimensional transducer arrays are generally used for transmission and reception of ultrasonic or acoustic waves during ultrasound diagnostic imaging. State of the art two-dimensional arrays generally include a flat array having on the order of about three thousand (3,000) transducer elements. In one type of ultrasound transducer design, all transducer elements of an array are attached and individually electrically connected to a surface of an integrated circuit (IC) via flip-chip technology using conductive bumps. The IC provides electrical control of the elements, such as, for beam forming, signal amplifying, etc.

One example of a typical design of an ultrasound transducer is illustrated in FIG. 1. The ultrasound transducer 10 includes a flat array of acoustic elements 12 that are coupled to a surface of an integrated circuit 14 via flip-chip conductive bumps 16. A flip-chip underfill material 18 is included within a region between the flip-chip conductive bumps 16, the integrated circuit 14 and the flat array of acoustic elements 12. Transducer 10 further includes a transducer base 20 and an interconnection cable 22. Interconnection cable 22 is for interconnecting between the integrated circuit 14 and an external cable (not shown). Integrated circuit 14 is electrically coupled to the interconnection cable 22 via wirebonded wires 24, using techniques known in the art.

Flip-chip assembly is a technique that allows attachment of a bare integrated circuit (IC) chip directly to a substrate in a face-down configuration. An IC chip can also be referred to as a die. With flip-chip assembly, the electrical connections between the IC chip and the substrate is achieved via conductive “bumps”. The height of the conductive bumps defines the distance between the IC chip and the substrate. Accordingly, flip-chip technology offers many advantages, including for example high density I/O count and short interconnect distance.

As technology miniaturization continues towards smaller and smaller dimensions, achieving a high density of connections in both X and Y directions for ultrasound transducer arrays is desired. However, the obtaining of a high density array of bumps in both X- and Y-directions is extremely difficult, if not impossible with prior methods. This is due in part because of normal process limitations, wherein the bumps have a low aspect ratio, e.g, an aspect ratio less than 1.

While there are applications that can benefit from the high I/O density, some applications may also require greater distance between the bare IC chip and the substrate than that achieved using known techniques. One example includes an application that requires greater capacitive or inductive isolation between the IC chip and substrate. Still other applications may require thermal isolation, mechanical isolation, or a sensor design in which the flip-chipped substrate needs to be separated into smaller parts after the flip-chip attachment. In the later instance, such a design requires greater separation to enable safe mechanical cutting of the smaller parts, such as with an ultrasound transducer or sensor.

There exist a number of different bumping techniques known in the art, for example, printed conductive polymer, stud bumping, solder ball bumping, and bumping through electroplating. However, none of the known bumping techniques allow for consistent production of bumps having an aspect ratio of foot print (width) to height greater than 1. Aspect ratio is defined as a ratio of a width dimension of a bump to a height of the bump.

Accordingly, an improved ultrasound transducer and method of making the same for overcoming the problems in the art is desired.

According to one embodiment of the present disclosure, an ultrasound transducer comprises an integrated circuit and an array of acoustic elements coupled to the integrated circuit via flip chip bumps. The flip chip bumps comprise high aspect ratio bumps having an aspect ratio greater than 1:1. The aspect ratio comprises a ratio of a bump height to a bump width.

FIG. 1 is a plan view of a conventional ultrasound sensor;

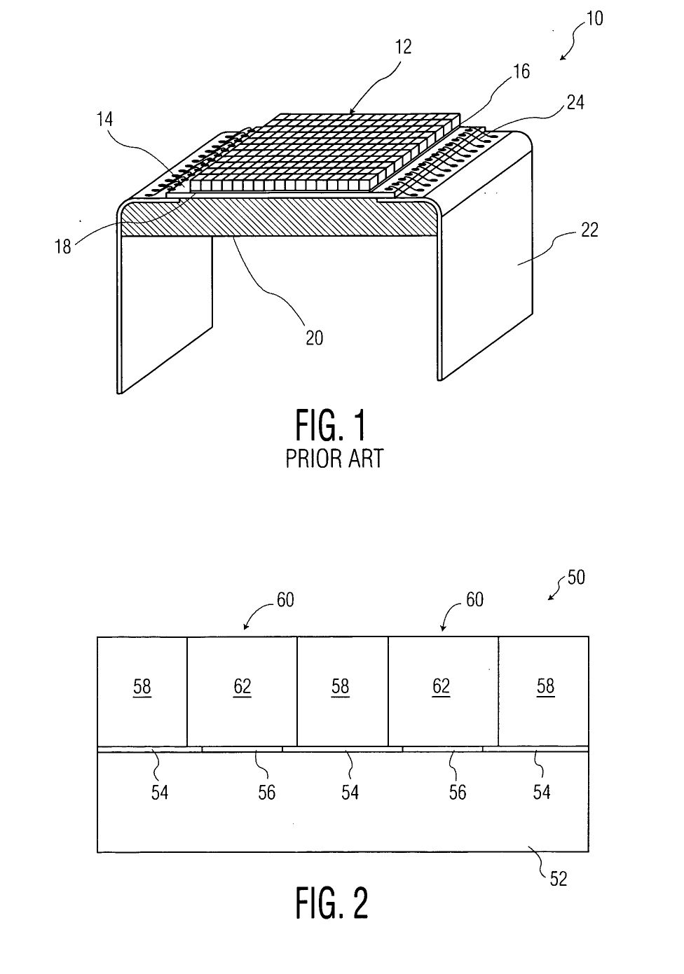

FIGS. 2-5 are cross-sectional views of steps in the formation of high aspect ratio flip-chip bumps for use in a two dimensional ultrasound transducer according to an embodiment of the present disclosure;

FIG. 6 is a cross-sectional view of a portion of an acoustic stack in the formation of a high aspect ratio flip-chip bump two dimensional ultrasound transducer according to an embodiment of the present disclosure;

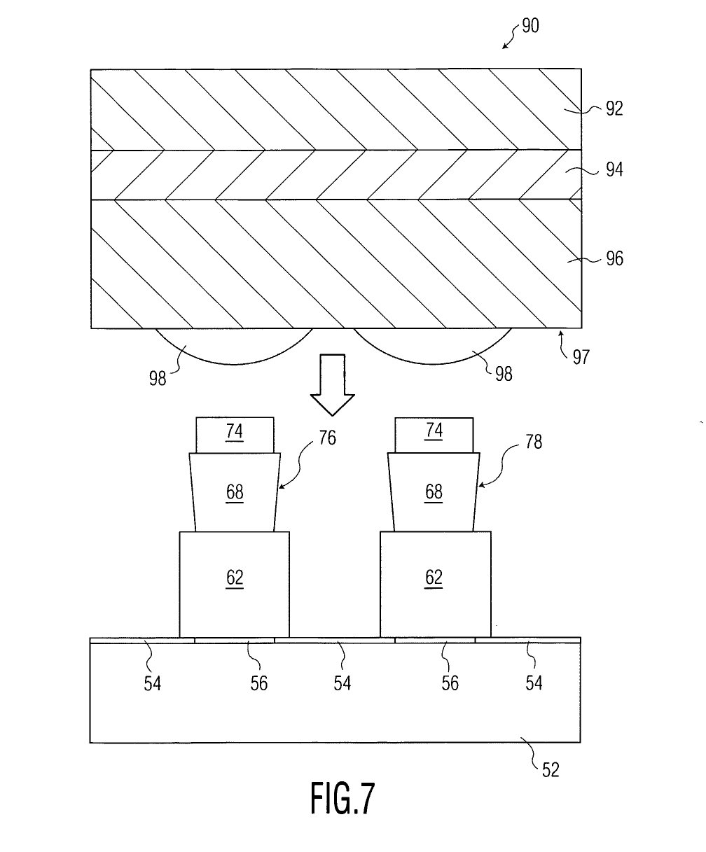

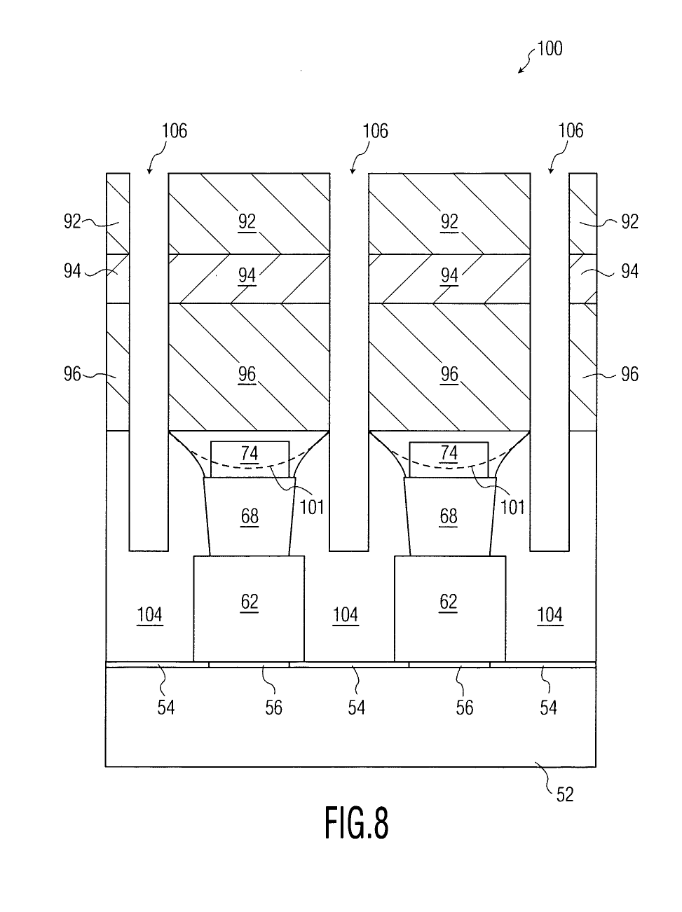

FIGS. 7-8 are cross-sectional views of steps in the formation of a high aspect ratio flip-chip two dimensional ultrasound transducer according to an embodiment of the present disclosure;

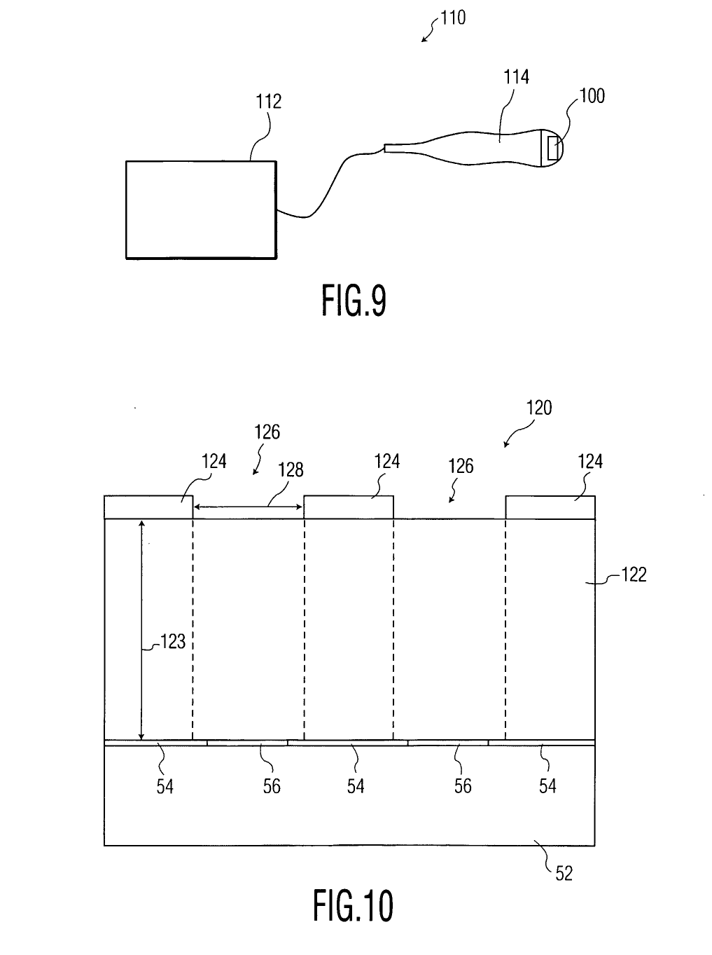

FIG. 9 is a block diagram view of an ultrasound diagnostic imaging system with an ultrasound transducer according to an embodiment of the present disclosure;

FIGS. 10-13 are cross-sectional views of steps in the formation of a high aspect ratio flip-chip two dimensional ultrasound transducer according to another embodiment of the present disclosure; and

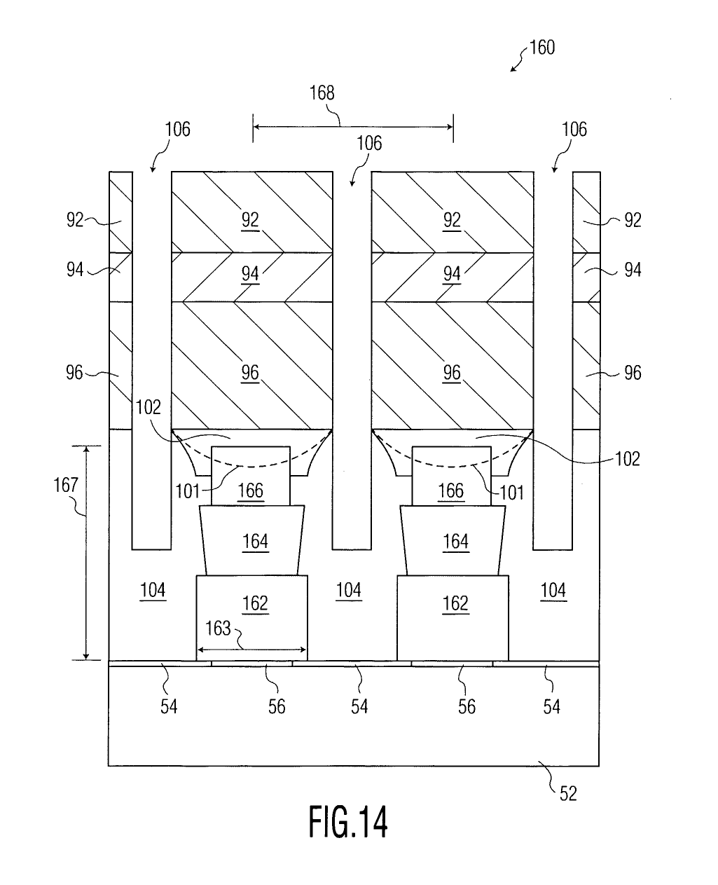

FIG. 14 is a cross-sectional view of a high aspect ratio flip-chip two dimensional ultrasound transducer according to another embodiment of the present disclosure.

In the figures, like reference numerals refers to like elements. In addition, it is to be noted that the figures are not drawn to scale.

In the manufacture of integrated circuits, a semiconductor wafer generally contains a number of integrated circuit die not yet separated into individual devices. Each of the integrated circuit die generally contains circuitry for performing desired functions according to the requirements of a particular integrated circuit application. For example, an integrated circuit application could include an ultrasound transducer application. Furthermore, the ultrasound transducer application can include a cardiac application, an abdominal application, a transosophageal (TEE) application, or other diagnostic or therapeutic ultrasound application.

With respect to ultrasound devices, a simplified ultrasound transducer build process sequence could include the following steps. For example, the process begins with obtaining a wafer containing desired ultrasound transducer ICs, e.g., from an application specific integrated circuit (ASIC) vendor. A process of wafer bumping according to one of the embodiments of the present disclosure is performed on the wafer. Subsequent to wafer bumping, the wafer is thinned and separated into individual die, using standard techniques. A flip-chip operation is then performed. Following the flip-chip operation, a dicing operation provides separation of acoustic elements of an ultrasound transducer or sensor component. The sensor can then be attached to a frame, according to the requirements of the particular ultrasound transducer IC application.

According to one embodiment of the present disclosure, a high aspect ratio bump for flip-chip achieves a high density of connections in both X and Y directions of a two-dimensional matrix array, as well as enables having a bump pitch on the order of less than or equal to 100 μm. In contrast, with prior methods, the obtaining of a high density array of bumps in both X and Y directions of a two-dimensional matrix array was extremely difficult, if not impossible. That is, with the prior techniques, normal process limitations prevented the making of high density flip chip bumps having a pitch of less than or equal to 100 μm and further having an aspect ratio greater than 1.

According to one embodiment of the present disclosure, the high aspect ratio flip-chip bumps comprise multiple step plated bumps and a method of making the same. In the method of making the multiple step plated bumps, the aspect ratio limit (1:1—width:height) of a typical plated bump has been overcome. The embodiment includes multiple step plated bumps produced by the sequential plating of bumps on top of each other as discussed further herein.

Referring now to FIGS. 2-5, cross-sectional views of steps in the formation of high aspect ratio flip-chip bumps for use in a two dimensional ultrasound transducer according to an embodiment of the present disclosure are shown. In FIGS. 2-5, only a portion 50 of the transducer is shown for simplicity of illustration.

In FIG. 2, a portion of an integrated circuit is represented by substrate 52. Substrate 52 includes an active region of the integrated circuit having various circuit layers (not shown) of circuitry for performing at least one of control processing and signal processing functions of the ultrasound transducer probe. A passivation layer 54 overlies substrate 52 and includes any suitable dielectric, glass, or insulation layer. Passivation layer 54 contains openings (or apertures) 56. Openings 56 enable electrical connection from a bond pad on an uppermost layer of the IC to a bump, yet to be formed. The size of the openings 56 is determined according to the requirements of the particular IC application. In one embodiment, the width of openings 56 is on the order of 70 μm.

In a first layer plating step, substrate 52 is coated with a photo-resist 58. The photo-resist 58 is then processed using a suitable photo-lithography process (e.g., expose, develop, and remove) for producing openings 60 in the photo-resist. The openings 60 in the photo-resist correspond to locations for desired first layer flip-chip bumps, and generally coinciding with corresponding openings 56 in the passivation layer. Openings 60 also expose a top surface of the substrate 52 (e.g., a bond pad) within the opening 56 of the passivation layer 54. In one embodiment, the pitch of the openings 60 is on the order of 100 μm. In one embodiment, the method includes selecting a thickness of the photo-resist 58 to define a height dimension of the first layer portions of the flip-chip bumps.

In the next step, a suitable electrolytic process (e.g., gold, copper, indium or solder) plates first layer portions 62 of the flip-chip bumps within the openings 60 in the photo-resist 58 (including being plated within openings 56 in the passivation layer 54). However, prior to plating the first layer portions 62, the electrolytic process includes an initial step of creating a common electrode (not shown) on a top surface of the integrated circuit chip or ASIC for electroplating. The use of a common electrode in an electrolytic process is standard in the industry and thus discussed only briefly herein. In creating the common electrode, the wafer surface is covered by a very thin conductor layer (for example, gold) prior to coating the surface with photo-resist 58. The common electrode layer is deposited on top of the passivation layer, as well as, on top of all bond pads (shorting them during the electrolytic process). Then, photoresist 58 is applied as discussed herein, etc. Moreover, upon a completion of the desired bumps using the plating process as further discussed herein (in one embodiment, the desired bumps include three (3) levels), an etch process substantially completely removes the common electrode from the surface of the passivation layer, except from underneath the desired plated bumps. Accordingly, during the electrolytic process, the plating current does not go through the active layers of the integrated circuit chip or ASIC. The first layer photo-resist 58 remains in place subsequent to the plating of the first layer portions 62 of the flip-chip bumps. After the first layer plating is completed, the surface of the photo-resist may be planarized if necessary. The process is then repeated for a next layer plating step, as discussed herein below.

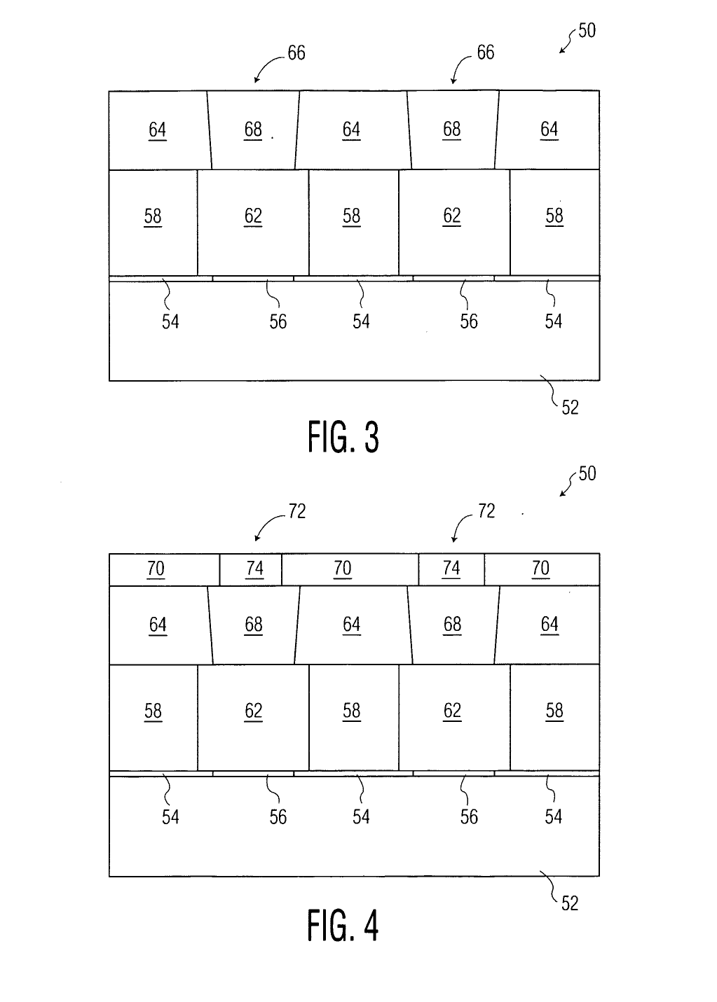

Referring now to FIG. 3, the next layer plating step comprises coating the wafer with a second layer of photo-resist 64, wherein the second layer overlies the first photo-resist 58 and first level flip-chip bumps 62. The second layer of photo-resist 64 is then processed using a suitable photo-lithography process (e.g., expose, develop, and remove) for producing openings 66 in the second layer photo-resist 64. The openings 66 in the second layer photo-resist 64 correspond to locations of the first layer flip-chip bumps 62 and expose a top surface of the first layer bumps. In one embodiment, the defined openings 66 in the second photo-resist 64 are made slightly smaller than the previous openings 60 to allow for small misalignments of the photo-resist mask. Furthermore, the openings 66 can comprise tapered openings. In one embodiment, the method includes selecting the thickness of the photo-resist 64 to define a height dimension of the second layer portions of the flip-chip bumps.

In the next step, a suitable electrolytic process (i.e., similar to the first electrolytic process) plates second layer portions 68 of the flip-chip bumps within the openings 66 in the photo-resist 64. The second layer photo-resist 64 remains in place subsequent to the plating of the second layer portions 68 of the flip-chip bumps. After the second layer plating is completed, the surface of the photo-resist may be planarized if necessary.

As shown in FIG. 3, the flip-chip bumps begin to take on a pyramid like structure. The process as described with respect to FIG. 3 is repeated for adding a subsequent layer to the flip-chip bumps as may be required for obtaining desired high aspect ratio conductive flip-chip bumps.

Referring now to FIG. 4, a next layer plating step comprises coating the wafer with a third layer of photo-resist 70, wherein the third layer overlies the second photo-resist 64 and second level flip-chip bumps 68. The third layer of photo-resist 70 is then processed using a suitable photo-lithography process (e.g., expose, develop, and remove) for producing openings 72 in the third layer photo-resist 70. The openings 72 correspond to locations of the second layer flip-chip bumps 68. In one embodiment, the defined openings 72 in the third photo-resist 70 are made slightly smaller than the previous openings 66 of the second layer to allow for small misalignments of the photo-resist mask. Furthermore, the openings 72 can comprise tapered openings.

In one embodiment, the width of the openings 72 is on the order of 40 μm. The reduced dimension of openings 72 also allows for creating an uppermost plated bump portion with a fine tip. The fine tip provides a mechanism that substantially reduces the potential for (i.e., substantially prevents) conductive adhesive shorts during a flip-chip placement operation. In one embodiment, the method includes selecting the thickness of the photo-resist 70 to define a height dimension of the third layer portions of the flip-chip bumps.

In the next step, a suitable electrolytic process (i.e., similar to the first electrolytic process) plates third layer portions 74 of the flip-chip bumps within the openings 72 in the photo-resist 70. The third layer photo-resist 70 remains in place subsequent to the plating of the third layer portions 74 of the flip-chip bumps. After the third layer plating is completed, the surface of the photo-resist may be planarized if necessary.

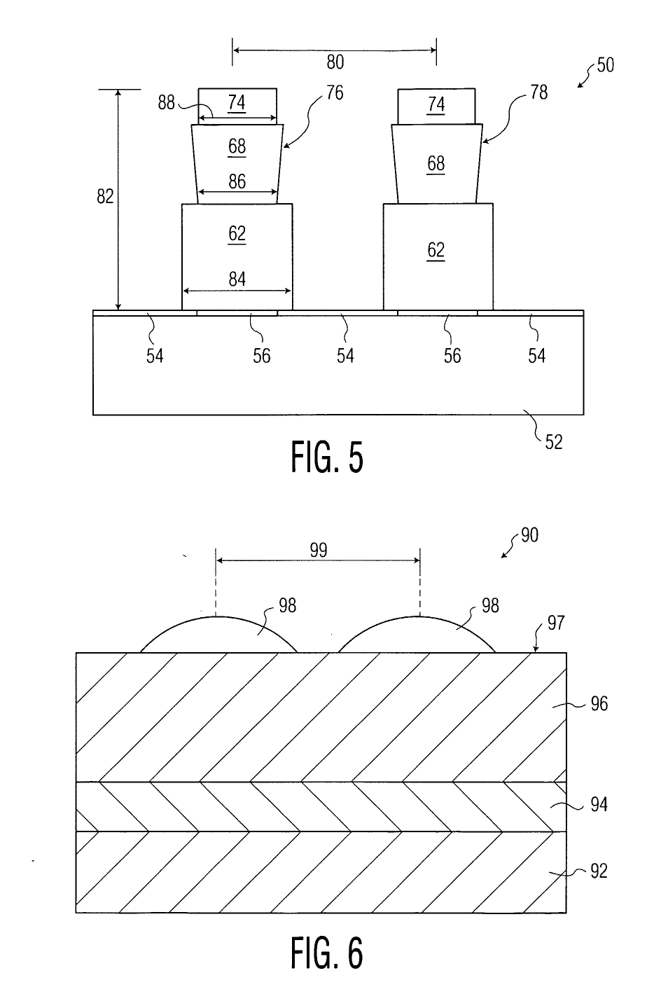

Referring now to FIG. 5, subsequent to formation of the third layer portions of the flip-chip bumps, the remaining portions of the first, second, and third photoresists (58,64,70) are removed using standard techniques. Accordingly, the flip-chip bumps 76 and 78 are produced. Flip-chip bumps (76,78) have a pitch generally represented by reference numeral 80. In one embodiment, the pitch 80 is on the order of 100 μm. Flip-chip bumps (76,78) also have height dimension generally represented by reference numeral 82. Furthermore, a width dimension of first, second, and third layer portions of bump 76 is generally represented by reference numerals 84, 86, and 88, respectively. In one embodiment, the height 82 is on the order of 100 microns, and the widths 84, 86, and 88, are on the order of 80, 60 and 40 microns, respectively.

For purposes of determining the aspect ratio of bump 76, the aspect ratio is equal to the height dimension 82 divided by the width dimension 84 of the first layer portion 62 of flip-chip bump 76. Accordingly, high aspect ratio bumps for flip-chip comprising multiple step plated bumps can be produced by the method described above. Furthermore, according to the embodiments of the present disclosure, the high aspect ratio bumps for flip-chip further comprise one or more of two (2), three (3), or four (4) step plated bumps with a desired pitch less than or equal to 100 μm and having an aspect ratio on the order of greater than one (1).

Advantages of the method for producing the multiple step plated bumps as disclosed herein include uniformity in height and cost. Uniformity in height can be achieved to within a few microns. In addition, a cost advantage is obtained by producing all bumps on the wafer at the same time versus one by one via a process of stud bumping.

The high density/high aspect ratio bumps of the present disclosure also provide mechanical robustness. In one embodiment of the present disclosure, an ultrasound transducer application comprises an array of ultrasound acoustic elements coupled to an integrated circuit via high aspect ratio flip-chip bumps, as disclosed herein. In connection with the ultrasound transducer, mechanical robustness is required due to a need to perform separation cuts of the transducer's acoustic material. Mechanical robustness is also required to provide a height that assures no damage occurs to the underlying integrated circuit (IC) during acoustic element/transducer separation cuts. In addition, the high density/high aspect ratio bumps for flip-chip are very advantageous in applications that require better electrical isolation and/or improved noise isolation.

Referring now to FIG. 6, the figure illustrates a cross-sectional view of a portion of an acoustic stack 90 suitable for use in the formation of a high aspect ratio flip-chip bump two dimensional ultrasound transducer according to an embodiment of the present disclosure. Acoustic stack 90 comprises, for example, a matching layer (ML) 92, single crystal layer 94 and dematching layer (DML) 96. In one embodiment, matching layer (ML) 92 has a height dimension on the order of 120 microns, single crystal layer 94 has a height dimension on the order of 120 microns and dematching layer (DML) 96 has a height dimension on the order of 270 microns. Accordingly, acoustic stack 90 has a height dimension on the order of 510 microns.

Conductive adhesive dots 98 (for example, any suitable conductive epoxy) are formed on a surface 97 of layer 96 using known screen printing techniques. A typical height of the dots is on the order of 30 μm. In one embodiment, conductive adhesive dots 98 have a pitch on the order of 150 μm (as indicated in FIG. 6 by reference numeral 99). Conductive adhesive dots 98 are provided in preparation for a flip-chip operation, to be discussed with respect to FIG. 7. Furthermore, surface 97 becomes a bottom surface of the acoustic stack 90 as will be better understood in connection with FIG. 7.

Referring now to FIGS. 7 and 8, the process of making a high aspect ratio flip-chip two dimensional ultrasound transducer according to an embodiment of the present disclosure continues with a flip-chip alignment, placement, and cure. In FIG. 7, the acoustic stack 90 of FIG. 6 is flipped and then aligned with respect to transducer portion 50. More particularly, the conductive adhesive dots 98 are aligned to corresponding ones of the high-aspect ratio flip-chip bumps (76,78) of portion 50. Once aligned, the acoustic stack 90 is placed upon the flip-chip bumps. Alignment and placement can be accomplished using a well known flip-chip bonder.

During the flip-chip placement step, the tips of the high-aspect ratio bumps displace the conductive adhesive sideways. In one embodiment, displacement is minimal in view of the structure of the multi-layered flip-chip bumps. That is, in one embodiment, the tips of the bumps are smaller than the underlying layer portions of the respective bump, thereby controlling an amount of sideways displacement of the conductive adhesive during a flip-chip placement operation. Accordingly, undesirable shorting of conductive adhesive between adjacent flip-chip bumps is advantageously avoided. As a result, the multi-layered high-aspect ratio flip-chip bump design of the present disclosure is very suitable for scaling to finer pitches.

Referring now to FIG. 8, the structure 100 is then placed in an oven for curing of the conductive adhesive. The cured conductive adhesive is indicated by reference numeral 102, wherein an original outline of the corresponding conductive dots is illustrated with a dashed line indicated by reference numeral 101.

Subsequent to curing of the conductive adhesive, an underfill material 104 is applied to the edge of the integrated circuit and acoustic stack. The underfill material spreads by capillary force across the surface of the acoustic stack, filling in the gap between the acoustic stack and the underlying IC. Thereafter, the structure 100 is diced using a suitable dicing operation for creating an array of individual acoustic elements from the acoustic stack 90. In one embodiment, the array comprises a two dimensional matrix array of acoustic elements.

The underfill 104 provides added mechanical strength to hold parts together, since the connection of the flip-chip bumps alone may not be adequate for the strength of the assembly. The underfill also provides a good hermetic seal of the joint between the acoustic stack and the IC. Still further, in the case of the flip-chip two-dimensional array, the underfill also provides mechanical support after the flip-chip is completed, wherein the dicing process separates the acoustic stack into individual elements. The separating cut needs to deeper than the last layer of the acoustic stack, but not too deep so as to reach the IC. Accordingly, the underfill functions also to support each individual element of the two-dimensional array.

Dicing creates gaps or trenches as indicated by reference numeral 106. With respect to the dicing operation and in order to make the process manufacturable, the height of the high-aspect ratio flip-chip bumps is needed to be in the range on the order of between 70-100 μm. This is important so as to assure a complete separation of the de-matching layer 96 of the acoustic stack 90 between newly created individual acoustic elements in an array of elements, without damaging the underlying IC.

Referring now to FIG. 9, the figure illustrates a block diagram view of an ultrasound diagnostic imaging system 110 with an ultrasound transducer according to an embodiment of the present disclosure. Ultrasound diagnostic imaging system 110 includes a base unit 112 adapted for use with ultrasound transducer probe 114. Ultrasound transducer probe 114 includes ultrasound transducer 100 as discussed herein. Base unit 112 includes suitable electronics for performing ultrasound diagnostic imaging according to the requirements of a particular ultrasound diagnostic application. Ultrasound transducer probe 114 couples to base unit 112 via a suitable connection, for example, an electronic cable, a wireless connection, or other suitable means. Ultrasound diagnostic imaging system 110 can be used for performing various types of medical diagnostic ultrasound imaging.

FIGS. 10-13 are cross-sectional views of steps in the formation of a high aspect ratio flip-chip two dimensional ultrasound transducer according to another embodiment of the present disclosure. In FIGS. 10-13, only a portion 120 of the transducer is shown for simplicity of illustration. Furthermore, the embodiment of FIG. 10 is similar to that of FIGS. 2-8, with the following differences. In this embodiment, the method of making flip-chip bumps comprises using a high aspect ratio photo-lithography process to produce high aspect ratio conductive features on the surface of a wafer.

One form of high aspect ratio photo-lithography includes a portion of the LIGA technique, developed by Karlsruhe Nuclear Research Center, Germany. In particular, the high aspect ratio photolithography step uses Synchrotron radiation instead of light. Synchrotron radiation comprises extremely parallel and intense x-ray radiation, that can be used in x-ray deep etch lithography.

With respect to the high aspect ratio photolithography (FIG. 10), a layer 122 of radiation sensitive resist (for example, a plastic) having a desired thickness is formed overlying a surface of the wafer. In one embodiment, the desired thickness, indicated by reference numeral 123) is selected according to the requirements of a given high-aspect ratio flip-chip bump application. For example, the desired thickness 123 can include a thickness in the range of 100-1000 μm. In another embodiment, the desired thickness is on the order of several hundred micrometers thick.

The layer of radiation sensitive resist 122 is then irradiated through a mask 124, the mask 124 containing flat X-ray absorbing material. Mask 124 further contains X-ray absorbing material features that are patterned corresponding to the locations of the desired flip-chip conductive bumps 126, for example, according to the requirements of a given ultrasound transducer application. A width dimension of a desired patterned location is indicated by reference numeral 128.

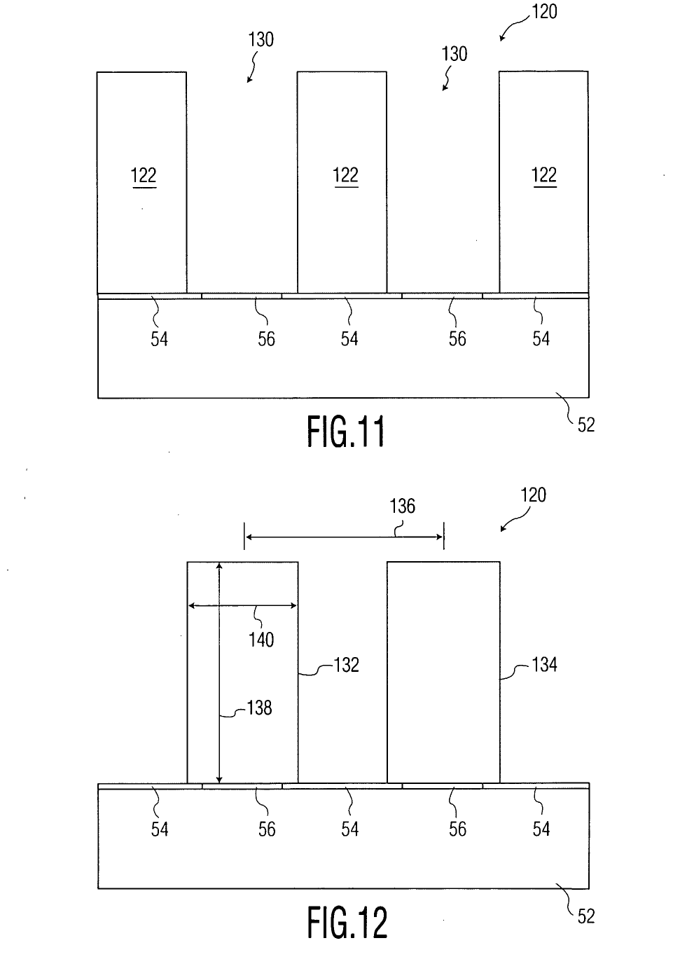

The irradiated areas of the resist 122 are subsequently removed by solvent action during a developing process, forming cavities 130 within the resist structure (FIG. 11). The cavities 130 of the resist structure are than filled by electrodeposition with a desired flip chip bump conductive material (e.g., metal). The resist is then removed using a suitable removal method, leaving metal features 132 and 134 as shown in FIG. 12.

The high aspect ratio electroformed metal features 132 and 134 that remain are then used as flip chip bumps. The flip chip bumps are separated by a pitch indicated by reference numeral 136. Bump 132 has a height dimension indicated by reference numeral 138 and a width dimension indicated by reference numeral 140. In one embodiment, the pitch 136 is on the order of 100 microns, the height 138 is on the order of 100 microns, and the width 140 is on the order of 40 microns.

Accordingly, the high aspect ratio Synchrotron radiation photo-lithography process produces the desired high density/high aspect ratio bumps. Furthermore, the method of using the Synchrotron radiation in x-ray deep etch lithography enables producing bumps on the surface of the wafer with an aspect ratio of up to 10, advantageously solving the flip-chip separation needs as discussed herein.

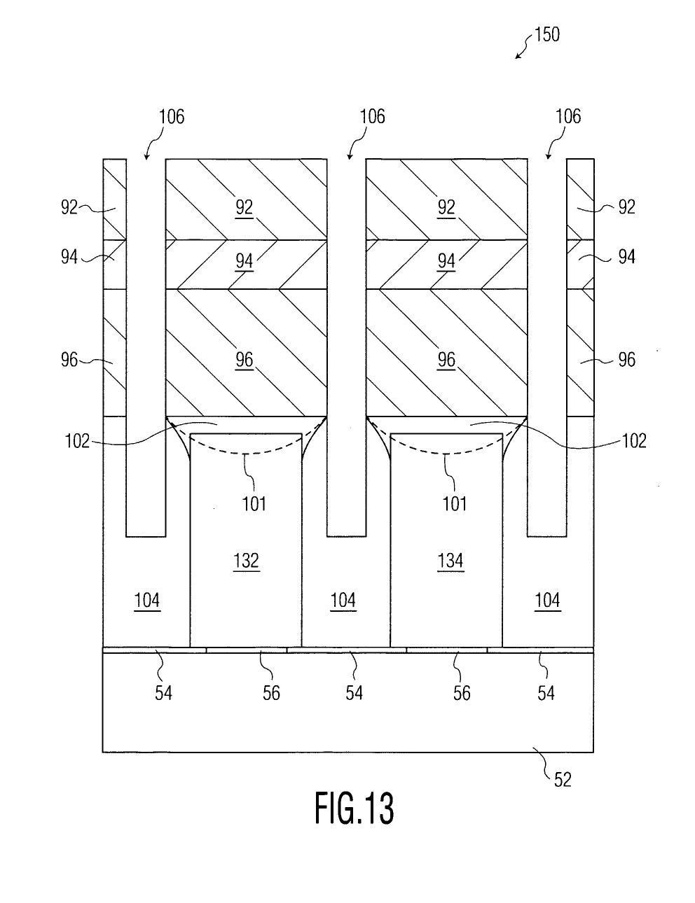

Referring now to FIG. 13, an acoustic stack 90 is flip-chip bonded to the structure 120 of FIG. 12, similarly as discussed herein above with respect to FIGS. 6-8. After a flip-chip alignment and placement, the structure 150 is placed in an oven for curing of the conductive adhesive. The cured conductive adhesive is indicated by reference numeral 102. Underfill material is indicated by reference numeral 104. The structure 150 is diced using a suitable dicing operation for creating an array of individual acoustic elements from the acoustic stack 90. Dicing creates trenches as indicated by reference numeral 106. The height of the high-aspect ratio flip-chip bumps (132,134) is in the range on the order of between 70-100 μm to assure a complete separation of the de-matching layer of the acoustic stack between newly created individual acoustic elements in an array of elements without damaging the underlying IC.

FIG. 14 is a cross-sectional view of a high aspect ratio flip-chip two dimensional ultrasound transducer according to another embodiment of the present disclosure. In FIG. 14, only a portion 160 of an ultrasound transducer is shown for simplicity of illustration. The embodiment of FIG. 14 is similar to that discussed herein with respect to FIGS. 2-8, with the following differences. In this embodiment, a method of making high aspect ratio flip-chip bumps comprises using stud bumping. Stud bumping includes, for example, gold ball bonding, as discussed further herein below.

To produce the desired high aspect ratio flip chip bumps, the stud bumping includes using multiple bumps placed on top of each other. The method includes forming a first layer of gold ball bonding bumps 162 overlying the wafer or substrate 52. Subsequently, a second layer of gold ball bonding bumps 164 are formed overlying the first layer of gold ball bonding bumps. The process of providing an additional layer of gold ball bonding bumps over a preceding layer of gold ball bonding bumps is repeated, as necessary, until the desired high aspect ratio flip-chip bumps are obtained for a given flip-chip bump application. For example, in the embodiment of FIG. 14, the method further includes forming a third layer of gold ball bonding bumps 164 overlying the second layer of gold ball bonding bumps 164.

The high aspect ratio flip-chip bumps of FIG. 14 are separated by a pitch indicated by reference numeral 168. The flip-chip bumps have a height dimension indicated by reference numeral 167 and a width dimension indicated by reference numeral 163. In one embodiment, the pitch 168 is on the order of 150 microns, the height 167 is on the order of 100 microns, and the width 163 is on the order of 80 microns. Furthermore, in one embodiment, the size of the gold ball bonding bumps of a succeeding layer are made smaller in at least one dimension than a size of corresponding gold ball bonding bumps of a preceding layer.

Referring still to FIG. 14, an acoustic stack 90 is flip-chip bonded to the structure 160, similarly as discussed herein above with respect to FIGS. 6-8. After a flip-chip alignment and placement, the structure 160 is placed in an oven for curing of the conductive adhesive. The cured conductive adhesive is indicated by reference numeral 102. Underfill material is indicated by reference numeral 104. The structure 160 is diced using a suitable dicing operation for creating an array of individual acoustic elements from the acoustic stack 90. Dicing creates trenches as indicated by reference numeral 106. The height of the high-aspect ratio flip-chip bumps is in the range on the order of between 70-100 μm to assure a complete separation of the de-matching layer of the acoustic stack between newly created individual acoustic elements in an array of elements without damaging the underlying IC.

Accordingly, the embodiments of the present disclosure enable the manufacture of an ultrasound sensor for an application requiring on the order of 2,500 to 100,000 flip-chip bumps in a two-dimensional array, having a pitch of 80-500 μm, a bump foot print of 40-150 μm, and further having an aspect ratio of greater than one (1).

Although only a few exemplary embodiments have been described in detail above, those skilled in the art will readily appreciate that many modifications are possible in the exemplary embodiments without materially departing from the novel teachings and advantages of the embodiments of the present disclosure. For example, the embodiments of the present disclosure can further include a semiconductor wafer comprising one or more integrated circuit die and an array of high aspect ratio flip-chip bumps coupled to a surface of the one or more integrated circuit die, wherein the high aspect ratio of the flip-chip bumps is greater than 1:1, as discussed herein. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

1. An ultrasound transducer (100), comprising:
an integrated circuit (52); and
an array of acoustic elements (92,94,96) coupled to the integrated circuit via flip chip bumps (76,78), wherein the flip chip bumps comprise high aspect ratio bumps having an aspect ratio greater than 1:1, further wherein the aspect ratio comprises a ratio of a bump height (82) to a bump width (84).

2. The ultrasound transducer of claim 1, further wherein the high aspect ratio bumps comprise at least two layered portions (62,68,74) of flip-chip bumps.

3. The ultrasound transducer of claim 2, further wherein a height (82) of the high-aspect ratio bumps comprises a sum of a height of each layer portion of the at least two layered portions of flip-chip bumps.

4. The ultrasound transducer of claim 2, wherein a width dimension (88) of an uppermost layered portion of the flip-chip bumps is on the order of less than 50% of a width dimension of a lowermost layered portion of the flip-chip bumps.

5. The ultrasound transducer of claim 1, wherein the high-aspect ratio flip-chip bumps have a pitch on the order of 100 μm.

6. The ultrasound transducer of claim 2, wherein first layered portions (62) of flip-chip bumps (76,78) are formed by a process of photoresist deposition, mask patterning, and etch processing to form openings in a first layer of photoresist at locations of the flip-chip bumps for the first layer, followed by electrolytic deposition of the a flip-chip bump material, wherein the electrolytic deposition fills the openings in the first layer of photoresist.

7. The ultrasound transducer of claim 6, wherein the flip-chip bump material comprises metal.

8. The ultrasound transducer of claim 6, further wherein next layered portions (68) of flip-chip bumps (76,78) are formed by a process of photoresist deposition, mask patterning, and etching processing to form openings in a next layer of photoresist at locations of the flip-chip bumps for the next layer, followed by electrolytic deposition of the a flip-chip bump material, wherein the electrolytic deposition fills the openings in the next layer of photoresist.

9. The ultrasound transducer of claim 8, further wherein the openings in the next layer are smaller than the openings in the first layer.

10. The ultrasound transducer of claim 2, wherein a first layered portion (62) has a first width dimension and a subsequent layered portion (68,74) has a subsequent width dimension, the subsequent width dimension being less than the first width dimension.

11. The ultrasound transducer of claim 1, wherein the flip chip bumps (132,134) further comprise high-aspect ratio electroformed metal features.

12. The ultrasound transducer of claim 11, further wherein the electroformed metal features are formed using an x-ray deep etch lithography process.

13. The ultrasound transducer of claim 1, wherein the high aspect ratio bumps (76,78) further comprise one of two (2), three (3), or four (4) step plated bumps.

14. The ultrasound transducer of claim 1, wherein the flip chip bumps further comprise stud bumps of a first layer and stud bumps of a next layer, the stud bumps of the next layer being coupled on top of corresponding stud bumps of a previous layer.

15. The ultrasound transducer of claim 14, further wherein the stud bumps of a next layer comprise bumps with a smaller width dimension than a width dimension of the stud bumps of a previous layer.

16. The ultrasound transducer of claim 14, further wherein the flip chip bumps comprise multiple layer gold ball bonding stud bumps.

17. The ultrasound transducer of claim 1, further comprising a matrix transesophageal transducer designed for ultrasound heart imaging through an esophageal wall and further comprising on the order of 2,500 to 3,000 acoustic elements.

18. An ultrasound diagnostic imaging system (110) adapted for use with an ultrasound transducer (100), said ultrasound transducer comprising:
an integrated circuit (52); and
an array of piezoelectric elements (92,94,96) coupled to the integrated circuit via flip chip bumps (76,78), wherein the flip chip bumps comprise high aspect ratio bumps having an aspect ratio greater than 1:1, further wherein the aspect ratio comprises a ratio of a bump height (82) to a bump width (84).

19. A method of fabricating an ultrasound transducer (100), comprising:
forming an array of flip chip bumps (76,78) on an integrated circuit (52), the flip chip bumps comprising high aspect ratio bumps having an aspect ratio greater than 1:1; and
coupling an array of piezoelectric elements (92,94,96) to the integrated circuit via the high aspect ratio bumps.

20. The method of claim 19, wherein the high aspect ratio bumps comprise at least two layered portions of flip-chip bumps.

21. The method of claim 20, wherein a width dimension of an uppermost layered portion of the flip-chip bumps is on the order of less than 50% of a width dimension of a lowermost layered portion of the flip-chip bumps.

22. The method of claim 20, wherein first layered portions of flip-chip bumps are formed by a process of photoresist deposition, mask patterning, and etch processing to form openings in a first layer of photoresist at locations of the flip-chip bumps for the first layer, followed by electrolytic deposition of the a flip-chip bump material, wherein the electrolytic deposition fills the openings in the first layer of photoresist, and further wherein next layered portions of flip-chip bumps are formed by a process of photoresist deposition, mask patterning, and etching processing to form openings in a next layer of photoresist at locations of the flip-chip bumps for the next layer, followed by electrolytic deposition of the a flip-chip bump material, wherein the electrolytic deposition fills the openings in the next layer of photoresist.

23. The method of claim 19, wherein the flip chip bumps further comprise high-aspect ratio electroformed metal features.

24. The method of claim 23, further wherein the electroformed metal features are formed using an x-ray deep etch lithography process.

25. The method of claim 19, wherein the high aspect ratio bumps further comprise one of two (2), three (3), or four (4) step plated bumps.

26. The method of claim 19, wherein the flip chip bumps further comprise stud bumps of a first layer and stud bumps of a next layer, the stud bumps of the next layer being coupled on top of corresponding stud bumps of a previous layer, further wherein the stud bumps of a next layer comprise bumps with a smaller width dimension than a width dimension of the stud bumps of a previous layer.

27. The method of claim 19, wherein the integrated circuit has a thickness on the order of approximately 5-50 μm.

28. A semiconductor wafer, comprising:
one or more integrated circuit die; and
an array of high aspect ratio flip-chip bumps coupled to a surface of the one or more integrated circuit die, wherein the high aspect ratio of the flip-chip bumps is greater than 1:1.

29. The semiconductor wafer of claim 28, wherein the high aspect ratio is on the order of 10:1.

30. The semiconductor wafer of claim 28, further comprising an array of acoustic elements of one or more ultrasound transducers, the array of acoustic elements being coupled to the one or more integrated circuit die via the high aspect ratio flip chip bumps, further wherein the one or more integrated circuit die includes circuitry for performing at least one of control processing and signal processing functions of an ultrasound transducer.

31. The semiconductor wafer of claim 28, further wherein the high aspect ratio bumps comprise at least two layered portions of flip-chip bumps.

32. The semiconductor wafer of claim 31, wherein a width dimension of an uppermost layered portion of the flip-chip bumps is on the order of less than 50% of a width dimension of a lowermost layered portion of the flip-chip bumps.

33. The semiconductor wafer of claim 31, wherein first layered portions of flip-chip bumps are formed by a process of photoresist deposition, mask patterning, and etch processing to form openings in a first layer of photoresist at locations of the flip-chip bumps for the first layer, followed by electrolytic deposition of the a flip-chip bump material, wherein the electrolytic deposition fills the openings in the first layer of photoresist, and further wherein next layered portions of flip-chip bumps are formed by a process of photoresist deposition, mask patterning, and etching processing to form openings in a next layer of photoresist at locations of the flip-chip bumps for the next layer, followed by electrolytic deposition of the a flip-chip bump material, wherein the electrolytic deposition fills the openings in the next layer of photoresist.

34. The semiconductor wafer of claim 28, wherein the flip chip bumps further comprise high-aspect ratio electroformed metal features.

35. The semiconductor wafer of claim 34, further wherein the electroformed metal features are formed using an x-ray deep etch lithography process.

36. The semiconductor wafer of claim 28, wherein the high aspect ratio bumps further comprise one of two (2), three (3), or four (4) step plated bumps.

37. The semiconductor wafer of claim 28, wherein the flip chip bumps further comprise stud bumps of a first layer and stud bumps of a next layer, the stud bumps of the next layer being coupled on top of corresponding stud bumps of a previous layer, further wherein the stud bumps of a next layer comprise bumps with a smaller width dimension than a width dimension of the stud bumps of a previous layer.
